(19) United States
(12) Patent Application Publication
(10) Pub. No.: US 2008/0158775 A1
(43) Pub. Date: Jul. 3, 2008

(54) Semiconductor device and method for fabricating the same

(75) Inventors: Satoshi Seo, Kyoto (JP); Tetsuya Ueda, Osaka (JP); Makoto Tsutsue, Shiga (JP)

Correspondence Address: MCDERMOTT WILL & EMERY LLP, 600 13TH STREET, NW, WASHINGTON, DC, 20005-3096, US

(73) Assignee: MATSUSHITA ELECTRIC CO., LTD., Osaka (JP)

(21) Appl. No.: 12/071,742

(22) Filed: Feb. 26, 2008

Related U.S. Application Data
(62) Division of application No. 11/200,115, filed on Aug. 10, 2005.

(30) Foreign Application Priority Data
Sep. 14, 2004 (JP) 2004-266402

(51) Int. Cl. H01G 4/228; H01L 21/20

(52) U.S. Cl. 361/309; 438/393; 257/E21.008

(57) ABSTRACT

A semiconductor device has a MIM capacitor including a first insulating film formed on a semiconductor substrate, a lower electrode composed of a first metal film formed on the first insulating film, a capacitor insulating film formed on the lower electrode, and an upper electrode composed of a second metal film formed on the capacitor insulating film. The semiconductor device further has a lower interconnect composed of the first metal film formed on the first insulating film and an upper interconnect composed of the second metal film formed on the lower interconnect. The upper interconnect and the upper electrode are formed integrally.

### CROSS-REFERENCE TO RELATED APPLICATIONS

The teachings of Japanese Patent Application JP 2004-266402, filed Sep. 14, 2004, are entirely incorporated herein by reference, inclusive of the specification, drawings, and claims.

### BACKGROUND OF THE INVENTION

The present invention relates to a semiconductor device comprising a MIM (Metal-Insulator-Metal) capacitor and to a method for fabricating the same.

In recent years, a study has been pursued on the one-chip integration of an analog device and a CMOS logic device. In the meantime, the CMOS logic device has been increasingly miniaturized year after year so that, to reduce an interconnect resistance in a MOS transistor with a gate length of 0.1 μm or less, the use of copper (Cu), which is a low-resistivity material, as an interconnect material has been studied, while a damascene process has been under study as a method for fabricating interconnects. As miniaturization proceeds, the degree of integration of the transistor tends to increase more and more and the total number of interconnects in a CMOS logic device tends to increase. These trends toward the miniaturization of a semiconductor device and a multilayer interconnect configuration have caused the problem of how to form a high-capacitance capacitor in an analog device without interfering with the achievement of higher device integration.

As an example in which a high-capacitance capacitor is formed in an analog device, there is a semiconductor device comprising a MIM capacitor formed by a damascene process. The MIM capacitor is composed of a metal lower electrode and a metal upper electrode opposing each other with a capacitor insulating film interposed therebetween. Because a thin-film technology allows the lower electrode, the capacitor insulating film, and the upper electrode to be formed thinner than in a conventional capacitor using polysilicon for a cell plate, the capacitor can be formed to have a high capacitance without interfering with the achievement of higher integration (see, e.g., Patent Document 1: Japanese Laid-Open Patent Publication No. 2002-217373).

Referring to the drawings, a description will be given herein below to a conventional method for fabricating a semiconductor device comprising a MIM capacitor.

FIGS. 7A to 7E are cross-sectional views illustrating the process steps of fabricating a conventional semiconductor device comprising a MIM capacitor. As typically shown in FIG. 7A, a MIM capacitor formation region MIM and an interconnect formation region Rlogic are depicted as the surface regions of a semiconductor substrate.

First, as shown in FIG. 7A, a first insulating film 1 is formed on the semiconductor substrate (not shown) formed with a semiconductor element such as a transistor. Then, a first metal film 2 is deposited by CVD or sputtering on the first insulating film 1.

Next, as shown in FIG. 7B, a second insulating film 3 is deposited by CVD on the first metal film 2.

Next, as shown in FIG. 7C, a resist mask 4 having an opening in the interconnect formation region Rlogic is formed by photolithography on the second insulating film 3 to cover the MIM capacitor formation region MIM. Then, the second insulating film 3 is patterned by dry etching using the resist mask 4. Thereafter, the resist mask 4 is removed by ashing using an oxidized plasma.

Next, as shown in FIG. 7D, a second metal film 5 is deposited by CVD or sputtering to cover the entire surface of the semiconductor substrate.

Next, as shown in FIG. 7E, the second metal film 5, the second insulating film 3, and the first metal film 2 are patterned by photolithography and dry etching to form a MIM capacitor 6 composed of an upper electrode 5a, a capacitor insulating film 3a, and a lower electrode 2a as well as an interconnect 7 composed of an upper interconnect 5b and a lower interconnect 2b.

### SUMMARY OF THE INVENTION

However, the conventional method for fabricating the semiconductor device comprising the MIM capacitor encounters the following problems.

As shown in FIG. 7C, the conventional method for fabricating the semiconductor device comprising the MIM capacitor covers the second insulating film 3 with the resist mask 4 to pattern the second insulating film 3 serving as the capacitor insulating film 3a of the MIM capacitor. Consequently, as the resist mask 4 is vaporized in the ashing after patterning, the upper and side surfaces of the capacitor insulating film 3a are exposed to the oxygen plasma. Since the capacitor insulating film is composed herein of, e.g., a silicon dioxide film (SiO₂), SiO₂ covalent bonds in the upper and side surfaces of the capacitor insulating film are broken upon exposure to the oxygen plasma so that physical etching occurs. This causes roughness in the upper and side surfaces of the capacitor insulating film, degrades the surface flatness thereof, and lowers the breakdown voltage thereof so that a dielectric breakdown occurs disadvantageously. In the case where dangling bonds are caused by exposure to the oxygen plasma in the upper and side surface of the capacitor insulating film, electrons are brought into an unstable and chemically active state so that the upper and side surfaces of the capacitor insulating film are contaminated with an impurity and the like. This leads to the faulty operation of the MIM capacitor, the lowering of a production yield, and the degradation of device reliability.

Further, in the conventional semiconductor device comprising the MIM capacitor, the MIM capacitor is electrically independent of the other elements and interconnects for extracting the upper electrode has not been formed. As a result, a new contact hole or an interconnect layer for extracting the upper electrode become necessary, which interferes with the miniaturization of the semiconductor device having the MIM capacitor. In addition, to form a new contact hole or interconnect layer for extracting the upper electrode, the number of steps in the fabrication process for the semiconductor device has been increased disadvantageously.

An object of the present invention is to provide a method for fabricating a semiconductor device having a high-reliability MIM capacitor.

A semiconductor device according to an aspect of the present invention is a semiconductor device having a MIM capacitor including a first insulating film formed on a semiconductor substrate, a lower electrode composed of a first metal film formed on the first insulating film, a capacitor insulating film formed on the lower electrode, and an upper electrode composed of a second metal film formed on the capacitor insulating film, the semiconductor device including: a lower interconnect composed of the first metal film formed on the first insulating film; and an upper interconnect composed of the second metal film formed on the lower interconnect, wherein the upper interconnect and the upper electrode are formed integrally.

The semiconductor device having the MIM capacitor according to the aspect of the present invention can further be miniaturized than a semiconductor device in which a contact hole and an interconnect layer each for extracting the upper electrode of a MIM capacitor are newly formed in an upper layer.

Preferably, the semiconductor device according to the aspect of the present invention further includes: a second insulating film formed on the first insulating film and having a lower electrode trench and an interconnect trench, wherein the lower electrode is buried in the lower electrode trench and the lower interconnect is buried in the interconnect trench.

In the semiconductor device according to the aspect of the present invention, the lower electrode has upper and side surfaces thereof covered with the capacitor insulating film.

Preferably, the semiconductor device according to the aspect of the present invention further includes: a third insulating film formed over the lower electrode and the lower interconnect to serve as the capacitor insulating film; and a fourth insulating film formed on the third insulating film, wherein an opening is formed in the portion of the fourth insulating film which is located over the lower electrode, a contact hole extending through the third and fourth insulating films is formed in the respective portions of the third and fourth insulating films which are located over the lower electrode, the upper electrode is formed on the portion of the capacitor insulating film composed of the third insulating film which is exposed in the opening, and the upper interconnect is formed in the contact hole to be connected to the lower interconnect.

In the semiconductor device according to the aspect of the present invention, the opening and the contact hole are preferably separated from each other by the fourth insulating film and the upper electrode and the upper interconnect are preferably connected to each other over the fourth insulating film.

A method for fabricating a semiconductor device according to an aspect of the present invention includes the steps of: (a) forming a first insulating film on a semiconductor substrate; (b) forming a lower electrode and a lower interconnect each composed of the first metal film on the first insulating film; (c) forming a capacitor insulating film on the lower electrode; and (d) forming an upper electrode composed of a second metal film on the capacitor insulating film and forming an upper interconnect composed of the second metal film on the lower interconnect, wherein the upper interconnect and the upper electrode are formed integrally.

In accordance with the method for fabricating a semiconductor device according to the aspect of the present invention, the upper and side surfaces of the capacitor insulating film of the MIM capacitor are protected from being exposed to an oxygen plasma so that the flatness of the capacitor insulating film of the MIM capacitor is retained. This renders it possible to prevent a dielectric breakdown resulting from the lowering of a breakdown voltage.

Preferably, the method for fabricating a semiconductor device according to the aspect of the present invention further includes, after the step (a) and prior to the step (b), the step of: forming the second insulating film on the first insulating film and then forming a lower electrode trench and an interconnect trench in the second insulating film, wherein the step (b) is for forming the lower electrode in the lower electrode trench and forming the lower interconnect in the interconnect trench.

In the method for fabricating a semiconductor device according to the aspect of the present invention, the step (b) is preferably for forming the first metal film on the first insulating film and then patterning the first metal film to form the lower electrode and the lower interconnect and the step (c) is preferably for forming the capacitor insulating film such that upper and side surfaces of the lower electrode are covered therewith.

In the method for fabricating a semiconductor device according to the aspect of the present invention, the step (c) is preferably for forming the third insulating film serving as the capacitor insulating film over the lower electrode and the lower interconnect, the method preferably further including, after the step (c) and prior to the step (d), the steps of: (e) forming a fourth insulating film on the third insulating film; (f) performing dry etching with respect to the portion of the fourth insulating film which is located over the lower electrode to a depth at which the third insulating film is not exposed to form an opening in the fourth insulating film; (g) after the step (f), forming a contact hole extending through the respective portions of the third and fourth insulating films which are located over the lower interconnect; and (h) after the step (g), removing the portion of the fourth insulating film which is remaining in the opening by wet etching, wherein the step (d) is preferably for forming the second metal film on the semiconductor substrate and then patterning the second metal film to integrally form the upper electrode and the upper interconnect.

Thus, in the semiconductor device according to the aspect of the present invention and the method for fabricating the same, the upper and side surfaces of the capacitor insulating film are protected from being exposed to an oxygen plasma so that the flatness of the capacitor insulating film is retained reliably and the lowering of the breakdown voltage thereof is prevented. In addition, the contamination of the capacitor insulating film resulting from exposure to the oxygen plasma can be prevented. Furthermore, the semiconductor device having the MIM capacitor can be miniaturized and the number of the fabrication process steps can be reduced.

### BRIEF DESCRIPTION OF THE DRAWINGS

FIG. 1 is a principal-portion cross-sectional view showing the structure of a semiconductor device according to a first embodiment of the present invention;

FIGS. 2A to 2E are principal-portion cross-sectional views illustrating the process steps in a method for fabricating the semiconductor device according to the first embodiment;

FIGS. 3A to 3C are principal-portion cross-sectional views illustrating the process steps in the method for fabricating the semiconductor device according to the first embodiment;

FIG. 4 is a principal-portion cross-sectional view showing the structure of a semiconductor device according to a second embodiment of the present invention;

FIGS. 5A to 5E are principal-portion cross-sectional views illustrating the process steps in a method for fabricating the semiconductor device according to the second embodiment;

FIGS. 6A to 6C are principal-portion cross-sectional views illustrating the process steps in the method for fabricating the semiconductor device according to the second embodiment; and

FIGS. 7A to 7E are principal-portion cross-sectional views illustrating the process steps in a conventional method for fabricating a semiconductor device having a MIM capacitor.

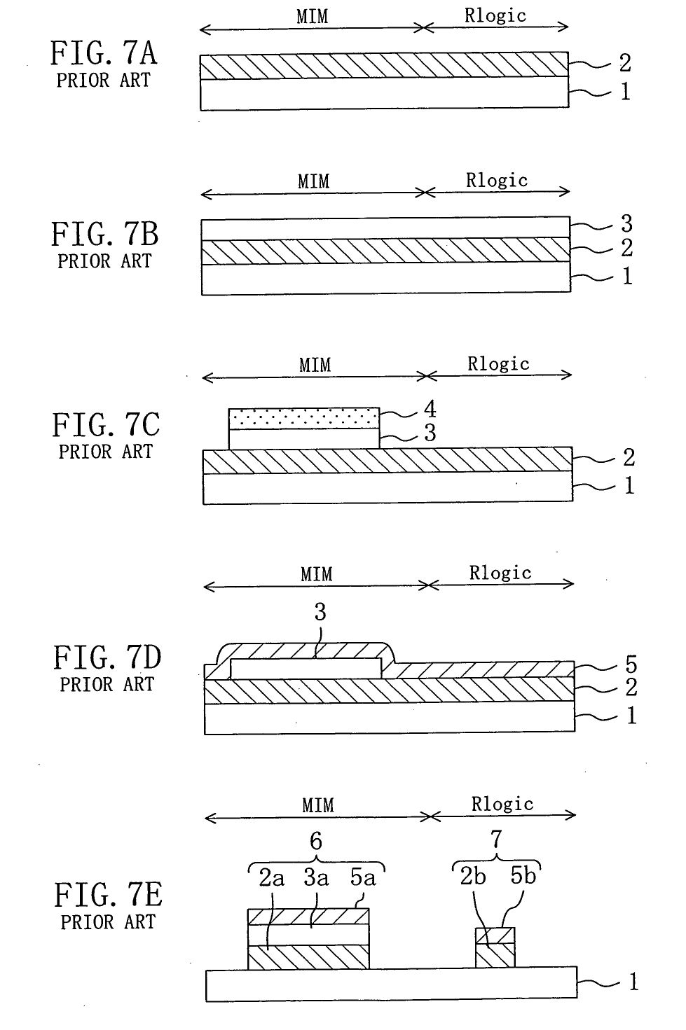

### DETAILED DESCRIPTION OF THE INVENTION

### Embodiment 1

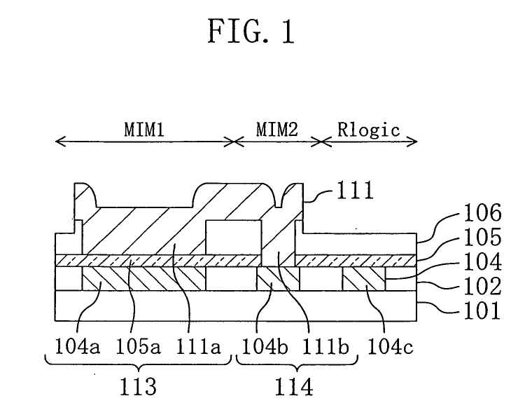

FIG. 1 is a cross-sectional view showing a semiconductor device comprising a MIM capacitor according to a first embodiment of the present invention. As shown in FIG. 1, a MIM capacitor formation region MIM1, a MIM capacitor extraction interconnect formation region MIM2, and an interconnect formation region Rlogic are depicted as the surface regions of a semiconductor substrate.

The MIM capacitor formation region MIM1 has: a first insulating film 101 formed on the semiconductor substrate (not shown); a second insulating film 102 formed on the first insulating film 101; a lower electrode 104a composed of a first metal film 104 buried in a lower electrode trench provided in the second insulating film 102; a capacitor insulating film 105a composed of a third insulating film 105 formed on the second insulating film 102 including the lower electrode 104a; a fourth insulating film 106 formed on the third insulating film 105; and an upper electrode 111a composed of a second metal film 111 formed on the portion of the capacitor insulating film 105a which is located in an opening provided in the fourth insulating film 106 to be located over the lower electrode 104a. The upper electrode 111a, the capacitor insulating film 105a, and the lower electrode 104a constitute a MIM capacitor 113.

The MIM capacitor extraction interconnect formation region MIM2 has: the first insulating film 101 formed on the semiconductor substrate (not shown); the second insulating film 102 formed on the first insulating film 101; a lower interconnect 104b composed of the portion of the first metal film 104 that has been buried in a lower interconnect trench provided in the second insulating film 102; the third insulating film 105 formed on the second insulating film 102 including the lower interconnect 104b; a fourth insulating film 106 formed on the third insulating film 105; and an upper interconnect 111b composed of the portion of the second metal film 111 that has been buried in a contact hole provided in the fourth and third insulating films 106 and 105 to be located over the lower interconnect 104b. The upper interconnect 111b and the lower interconnect 104b constitute a MIM capacitor extraction interconnect 114. The upper interconnect 111b has been formed integrally with the upper electrode 111a of the MIM capacitor 113 and connected electrically thereto.

The interconnect formation region Rlogic has: the first insulating film 101 formed on the semiconductor substrate (not shown); the second insulating film 102 formed on the first insulating film 101; an interconnect 104c composed of the portion of the first metal film 104 that has been buried in an interconnect trench provided in the second insulating film 102; the third insulating film 105 formed over the second insulating film 102 and the interconnect 104c; and the fourth insulating film 106 formed on the third insulating film 105.

The first embodiment is characterized in that the upper interconnect 111b has been formed integrally with the upper electrode 111a of the MIM capacitor 113 and the upper electrode 111a is extracted via the lower interconnect 104b connected electrically thereto. This allows further miniaturization of the semiconductor device having the MIM capacitor than in the case where a contact hole and an interconnect layer each for extracting the upper electrode of the MIM capacitor are newly formed in an upper layer.

### —Method for Fabricating Semiconductor Device of Embodiment 1—

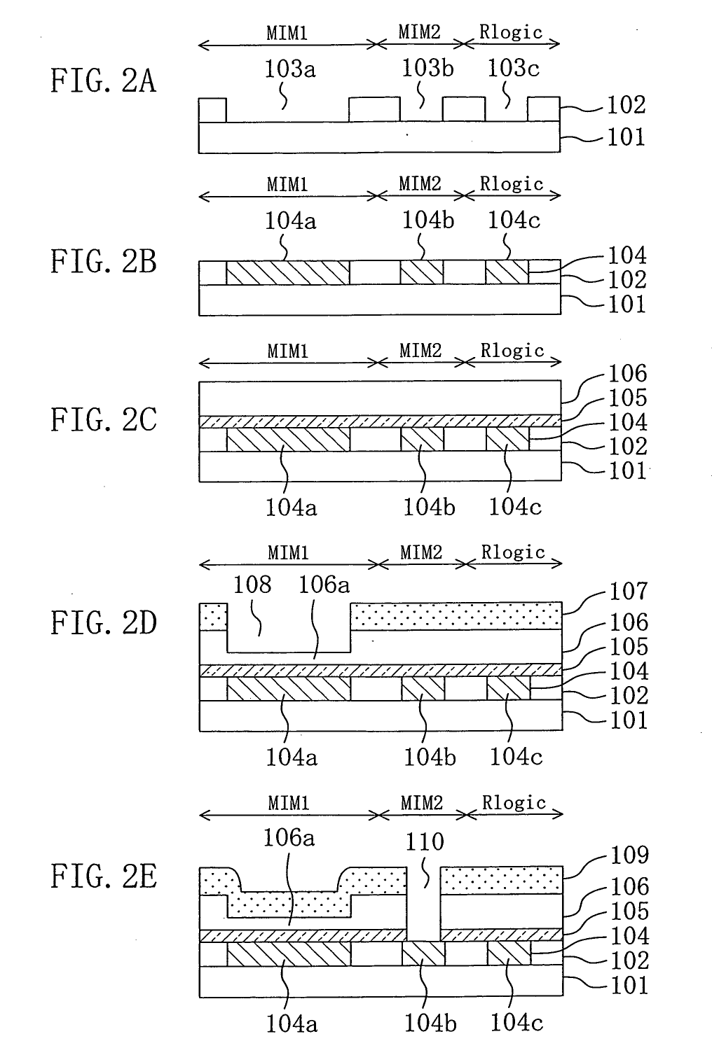

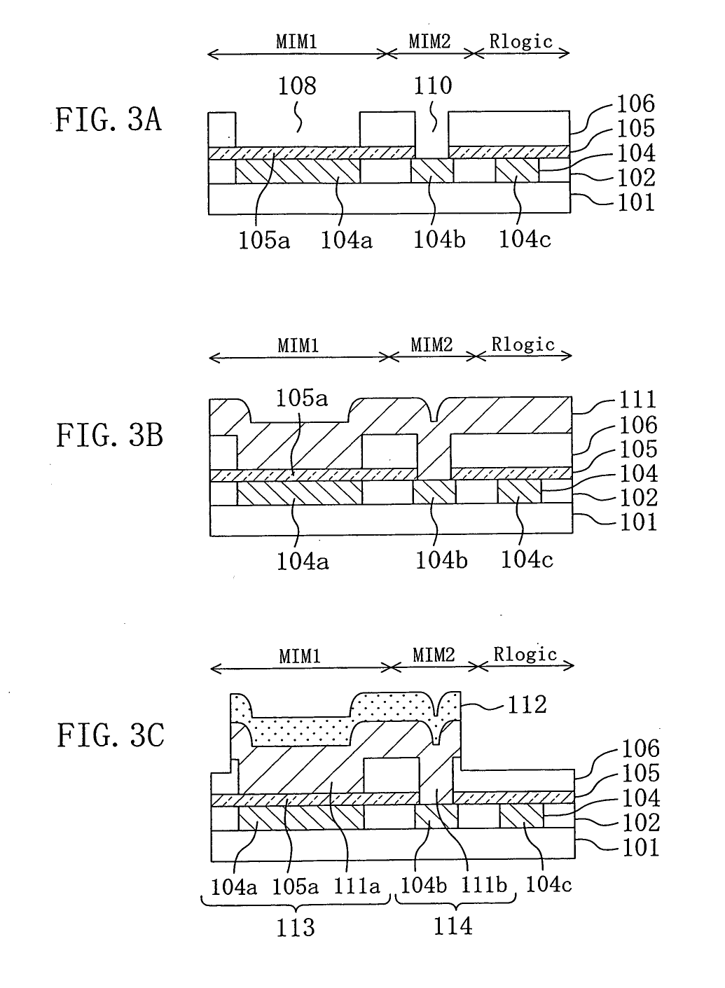

A method for fabricating the semiconductor device according to the first embodiment of the present invention will be described. FIGS. 2A to 2E and FIGS. 3A to 3C are cross-sectional views illustrating the process steps of fabricating the semiconductor device according to the first embodiment. As typically shown in FIGS. 2A and 3A, the MIM capacitor formation region MIM1, the MIM capacitor extraction interconnect formation region MIM2, and the interconnect formation region Rlogic are depicted as the surface regions of the semiconductor substrate.

First, as shown in FIG. 2A, the first insulating film 101 is formed on the semiconductor substrate (not shown) formed with a semiconductor element such as a transistor. Then, the second insulating film 102 composed of, e.g., a fluorine-doped silicon oxide film (FSG film) with a thickness of 300 nm is deposited by CVD on the first insulating film 101. Subsequently, a lower electrode trench 103a, an interconnect trench 103b, and an interconnect trench 103c are formed by photolithography and dry etching in the respective portions of the second insulating film 102 which are located in the MIM capacitor formation region MIM1, the MIM capacitor extraction interconnect formation region MIM2, and the interconnect formation region Rlogic.

Next, as shown in FIG. 2B, the first metal film (not shown) with a thickness of, e.g., 700 nm is deposited by CVD or sputtering to fill in the lower electrode trench 103a, the interconnect trench 103b, and the interconnect trench 103c formed in the second insulating film 102. Thereafter, the first metal is polished by CMP (Chemical Mechanical Polishing) to form the lower electrode 104a of the MIM capacitor, the lower interconnect 104b, and the interconnect 104c. For the first metal film 104, aluminum (Al) or copper (Cu), e.g., is used herein.

Next, as shown in FIG. 2C, the third insulating film 105 with a thickness of, e.g., 50 nm and the fourth insulating film 106 with a thickness of, e.g., 200 mm are deposited successively by CVD on the second insulating film 102 including the lower electrode 104a of the MIM capacitor, the lower interconnect 104b, and the interconnect 104c. As the third insulating film 105, a silicon nitride (SiN) film, e.g., is used herein. As the fourth insulating film 106, a silicon dioxide film (SiO₂), e.g., is used herein.

Next, as shown in FIG. 2D, a resist mask 107 having an opening over the lower electrode 104a is formed by photolithography on the fourth insulating film 106. Then, by a dry etching process using the resist mask 107, the fourth insulating film 106 is etched to a depth at which the third insulating film 105 is not exposed so that an opening 108 is formed. For example, the opening 108 at a depth of 150 nm is formed in the fourth insulating film 106 such that a fourth insulating film 106a remaining at the bottom of the opening 108 has a thickness of 50 nm. The purpose of etching the fourth insulating film 106 to a depth at which the third insulating film 105 is not exposed is to expose the third insulating film 105 in the MIM capacitor formation region MIM1 and prevent the third insulating film 105 from being exposed in each of the MIM capacitor extraction interconnect formation region MIM2 and the interconnect formation region Rlogic in the subsequent wet etching step.

Next, as shown in FIG. 2E, the resist mask 107 is removed and then a resist mask 109 having an opening over the lower interconnect 104b is formed by photolithography on the fourth insulating film 106. Then, by a dry etching process using the resist mask 109, each of the fourth and third insulating films 106 and 105 is etched to a point where the lower interconnect 104b is exposed so that a contact hole 110 is formed in the MIM capacitor extraction interconnect formation region MIM2.

Next, as shown in FIG. 3A, the resist mask 109 is removed and then the fourth insulating film 106a remaining in the opening 108 in the MIM capacitor formation region MIM1 is etched by a wet etching process using, e.g., an ammonia-hydrogen peroxide mixture so that the capacitor insulating film 105a composed of the third insulating film 105 is exposed in the opening 108 in the MIM capacitor formation region MIM1.

Next, as shown in FIG. 3B, the second metal film 111 with a thickness of, e.g., 900 nm is deposited by CVD or sputtering on the fourth insulating film 106 to fill in the opening 108 and the contact hole 110. For the second metal film 111, aluminum (Al) or copper (Cu) is used herein.

Next, as shown in FIG. 3C, a resist mask 112 having an opening in the interconnect formation region Rlogic is formed by photolithography on the second metal film 111 to cover the MIM capacitor formation region MIM1 and the MIM capacitor extraction interconnect formation region MIM2. Then, by a dry etching process using the resist mask 112, the second metal film 111 is etched to integrally form the upper electrode 111a in the MIM capacitor formation region MIM1 and the upper interconnect 111b in the MIM capacitor extraction interconnect formation region MIM2, whereby the MIM capacitor 113 composed of the upper electrode 111a, the capacitor insulating film 105a, and the lower electrode 104a and the MIM capacitor extraction interconnect 114 composed of the upper interconnect 111b and the lower interconnect 104b are formed.

The method for fabricating the semiconductor device according to the first embodiment allows the formation of the MIM capacitor 113 composed of the upper electrode 111a, the capacitor insulating film 105a, and the lower electrode 104a by performing wet etching with respect to the fourth insulating film 106a remaining in the opening 108 in the MIM capacitor formation region MIM1 and depositing the second metal film 111. This prevents a photoresist from being deposited on the capacitor insulating film 105a and protects the capacitor insulating film 105a from being exposed to an oxygen plasma used for ashing, thereby preventing the faulty operation of the MIM capacitor, the lowering of a production yield, and the degradation of device reliability due to a dielectric breakdown resulting from the degraded flatness of the capacitor insulating film and to the contamination of the capacitor insulating film.

The method for fabricating the semiconductor device according to the first embodiment also allows simultaneous formation of the upper electrode 111a of the MIM capacitor 113 and the upper interconnect 111b of the MIM capacitor extraction interconnect 114. This obviates the necessity to further form a contact hole and an interconnect layer which are necessary for extracting the MIM capacitor when the MIM capacitor is formed independently of the other elements and allows a reduction in the number of steps of forming the semiconductor device having the MIM capacitor.

### Embodiment 2

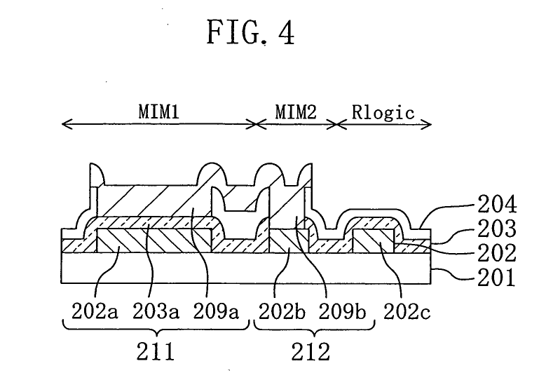

FIG. 4 is a cross-sectional view showing a semiconductor device comprising a MIM capacitor according to a second embodiment of the present invention. As shown in FIG. 4, a MIM capacitor formation region MIM1, a MIM capacitor extraction interconnect formation region MIM2, and an interconnect formation region Rlogic are depicted as the surface regions of a semiconductor substrate (not shown).

The MIM capacitor formation region MIM1 has: a first insulating film 201 formed on the semiconductor substrate (not shown); a lower electrode 202a composed of a first metal film 202 formed on the first insulating film 201; a capacitor insulating film 203a composed of a second insulating film 203 formed to cover the upper and side surfaces of the lower electrode 202a; a third insulating film 204 formed on the second insulating film 203; and an upper electrode 209a composed of a second metal film 209 formed on the portion of the capacitor insulating film 203a which is located in an opening provided in the third insulating film 204 to be located over the lower electrode 202a. The upper electrode 209a, the capacitor insulating film 203a, and the lower electrode 202a constitute a MIM capacitor 211.

The MIM capacitor extraction interconnect formation region MIM2 has: the first insulating film 201 formed on the semiconductor substrate (not shown); a lower interconnect 202b composed of the first metal film 202 formed on the first insulating film 201; the second insulating film 203 formed to cover the upper and side surfaces of the lower interconnect 202b; the third insulating film 204 formed on the second insulating film 203; and an upper interconnect 209b composed of the portion of the second metal film 209 that has been buried in a contact hole provided in the third and second insulating films 204 and 203 to be located over the lower interconnect 202b. The upper interconnect 209b and the lower interconnect 202b constitute a MIM capacitor extraction interconnect 212. The upper interconnect 209b has been formed integrally with the upper electrode 209a of the MIM capacitor 211 and connected electrically thereto.

The interconnect formation region Rlogic has the first insulating film 201 formed on the semiconductor substrate (not shown); an interconnect 202c composed of the first metal film 202 formed on the first insulating film 201; the second insulating film 203 formed to cover the upper and side surfaces of the interconnect 202c; and the third insulating film 204 formed on the second insulating film 203.

The second embodiment is characterized in that the upper interconnect 209b has been formed integrally with the upper electrode 209a of the MIM capacitor 211 and the upper electrode 209a is extracted via the lower interconnect 202b connected electrically thereto. This allows further miniaturization of the semiconductor device having the MIM capacitor than in the case where a contact hole and an interconnect layer each for extracting the upper electrode of the MIM capacitor are newly formed in an upper layer.

### —Method for Fabricating Semiconductor Device of Embodiment 2—

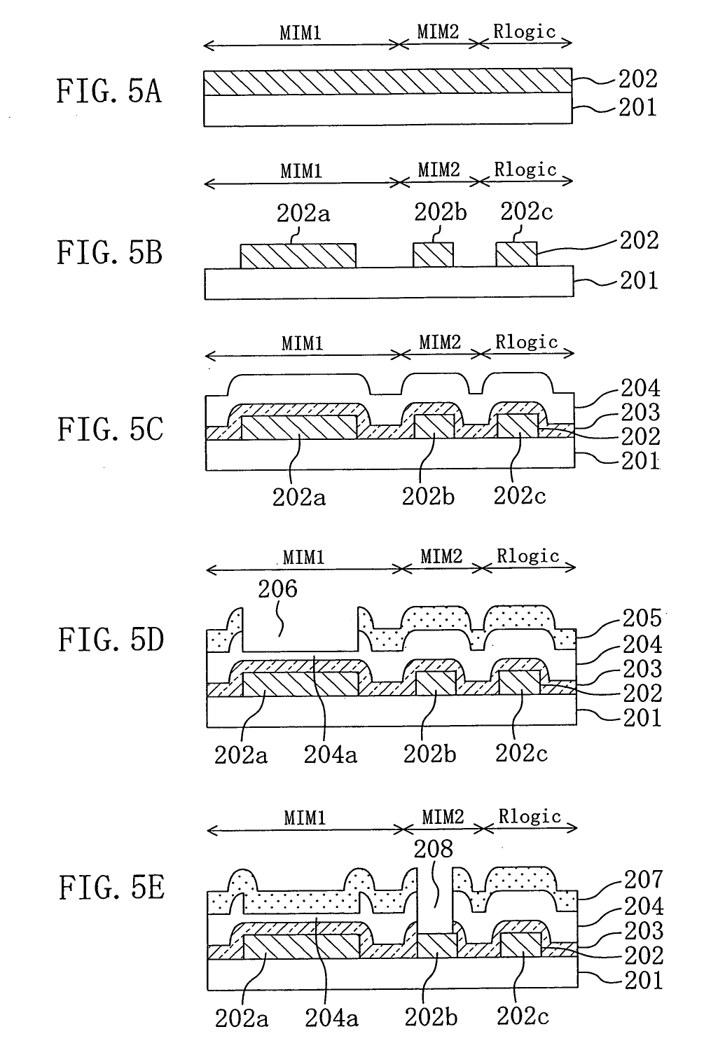

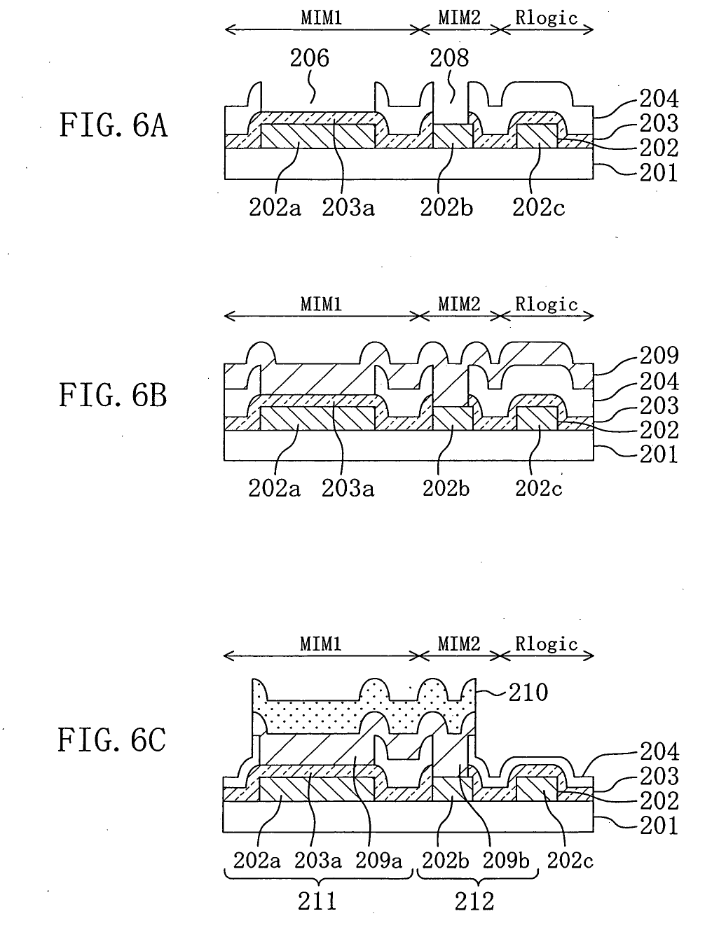

A method for fabricating the semiconductor device according to the second embodiment of the present invention will be described. FIGS. 5A to 5E and FIGS. 6A to 6C are cross-sectional views illustrating the process steps of fabricating the semiconductor device according to the second embodiment. As shown in FIGS. 5A and 5B, the MIM capacitor formation region MIM1, the MIM capacitor extraction interconnect formation region MIM2, and the interconnect formation region Rlogic are depicted as the surface regions of the semiconductor substrate (not shown).

First, as shown in FIG. 5A, the first insulating film 201 is formed on the semiconductor substrate (not shown) formed with a semiconductor element such as a transistor. Then, the first metal film 202 with a thickness of, e.g., 300 nm is deposited by CVD or sputtering on the first insulating film 201. For the first metal film 202, aluminum (Al) or copper (Cu), e.g., is used herein.

Next, as shown in FIG. 5B, the first metal film 202 is patterned by photolithography and dry etching to form the lower electrode 202a of the MIM capacitor, the lower interconnect 202b, and the interconnect 202c.

Next, as shown in FIG. 5C, the second insulting film 203 with a thickness of, e.g., 50 nm and the third insulating film 204 with a thickness of, e.g., 200 nm are deposited successively by CVD to cover the lower electrode 202a of the MIM capacitor, the lower interconnect 202b, and the interconnect 202c. As the second insulating film 203, a silicon nitride (SiN) film, e.g., is used herein. As the third insulating film 204, a silicon dioxide film (SiO₂), e.g., is used herein.

Next, as shown in FIG. 5D, a resist mask 205 having an opening over the lower electrode 202a is formed by photolithography on the third insulating film 204. Then, by a dry etching process using the resist mask 205, the third insulating film 204 is etched to a depth at which the second insulating film 203 is not exposed so that an opening 206 is formed. For example, the opening 206 at a depth of 150 nm is formed in the third insulating film 204 such that a third insulating film 204a remaining at the bottom of the opening 206 has a thickness of 50 nm. The purpose of etching the third insulating film 204 to a depth at which the second insulating film 203 is not exposed is to expose the second insulating film 203 in the MIM capacitor formation region MIM1 and prevent the second insulating film 203 from being exposed in each of the MIM capacitor extraction interconnect formation region MIM2 and the interconnect formation region Rlogic in the subsequent wet etching step.

Next, as shown in FIG. 5E, the resist mask 205 is removed and then a resist mask 207 having an opening over the lower interconnect 202b is formed by photolithography on the third insulating film 204. Then, by a dry etching process using the resist mask 207, each of the third and second insulating films 204 and 203 is etched to a point where the lower interconnect 202b is exposed so that a contact hole 208 is formed in the MIM capacitor extraction interconnect formation region MIM2.

Next, as shown in FIG. 6A, the resist mask 207 is removed and then the third insulating film 204a remaining in the opening 206 in the MIM capacitor formation region MIM1 is etched by a wet etching process using, e.g., an ammonia-hydrogen peroxide mixture so that the capacitor insulating film 203a composed of the second insulating film 203 is exposed in the opening 206 in the MIM capacitor formation region MIM1.

Next, as shown in FIG. 6B, the second metal film 209 with a thickness of, e.g., 900 nm is deposited by CVD or sputtering on the third insulating film 204 to fill in the opening 206 and the contact hole 208. For the second metal film 209, aluminum (Al) or copper (Cu) is used herein.

Next, as shown in FIG. 6C, a resist mask 210 having an opening in the interconnect formation region Rlogic is formed by photolithography on the second metal film 209 to cover the MIM capacitor formation region MIM1 and the MIM capacitor extraction interconnect formation region MIM2. Then, by a dry etching process using the resist mask 210, the second metal film 209 is etched to integrally form the upper electrode 209a in the MIM capacitor formation region MIM1 and the upper interconnect 209b in the MIM capacitor extraction interconnect formation region MIM2, whereby the MIM capacitor 211 composed of the upper electrode 209a, the capacitor insulating film 203a, and the lower electrode 202a and the MIM capacitor extraction interconnect 212 composed of the upper interconnect 209b and the lower interconnect 202b are formed.

The method for fabricating the semiconductor device according to the second embodiment allows the formation of the MIM capacitor 211 composed of the upper electrode 209a, the capacitor insulating film 203a, and the lower electrode 202a by performing wet etching with respect to the third insulating film 204a remaining in the opening 206 in the MIM capacitor formation region MIM1 and depositing the second metal film 209. This prevents a photoresist from being deposited on the capacitor insulating film 203a and protects the capacitor insulating film 203a from being exposed to an oxygen plasma used for ashing, thereby preventing the faulty operation of the MIM capacitor, the lowering of a production yield, and the degradation of device reliability due to a dielectric breakdown resulting from the degraded flatness of the capacitor insulating film and to the contamination of the capacitor insulating film.

The method for fabricating the semiconductor device according to the second embodiment also allows simultaneous formation of the upper electrode 209a of the MIM capacitor 211 and the upper interconnect 209b of the MIM capacitor extraction interconnect 212. This obviates the necessity to further form a contact hole and an interconnect layer which are necessary for extracting the MIM capacitor when the MIM capacitor is formed independently of the other elements and allows a reduction in the number of steps of forming the semiconductor device having the MIM capacitor.

The semiconductor device according to an aspect of the present invention and the method for fabricating the same are useful for a semiconductor device having a MIM capacitor and a fabrication method therefor.

1-2. (canceled)

3. The semiconductor device of having a MIM capacitor comprising a first insulating film formed on a semiconductor substrate, a lower electrode composed of a first metal film formed on the first insulating film, a capacitor insulating film formed on the lower electrode, and an upper electrode composed of a second metal film formed on the capacitor insulating film, the semiconductor device comprising:
a lower interconnect composed of the first metal film formed on the first insulating film; and
an upper interconnect composed of the second metal film formed on the lower interconnect,
wherein the upper interconnect and the upper electrode are formed integrally; and
the lower electrode has upper and side surfaces thereof covered with the capacitor insulating film.

4-7. (canceled)

8. A method for fabricating a semiconductor device, the method comprising the steps of:
(a) forming a first insulating film on a semiconductor substrate;
(b) forming a lower electrode and a lower interconnect each composed of the first metal film on the first insulating film;
(c) forming a capacitor insulating film on the lower electrode; and
(d) forming an upper electrode composed of a second metal film on the capacitor insulating film and forming an upper interconnect composed of the second metal film on the lower interconnect,
wherein the upper interconnect and the upper electrode are formed integrally, and
the step (b) is for forming the first metal film on the first insulating film and then patterning the first metal film to form the lower electrode and the lower interconnect, and
the step (c) is for forming the capacitor insulating film such that upper and side surfaces of the lower electrode are covered therewith.

9. (canceled)
